(19) United States
(12) Patent Application Publication
(10) Pub. No.: US 2009/0053623 A1
(43) Pub. Date: Feb. 26, 2009

(54) MASK FOR SEMICONDUCTOR DEVICE AND PATTERNING METHOD USING THE SAME

(76) Inventor: Jun-Seok Lee, Goyang-si (KR)

Correspondence Address: SHERR & VAUGHN, PLLC, 620 HERNDON PARKWAY, SUITE 200, HERNDON, VA, 20170, US

(21) Appl. No.: 12/192,082

(22) Filed: Aug. 14, 2008

(30) Foreign Application Priority Data
Aug. 23, 2007 (KR) 10-2007-0084931

(51) Int. Cl. G03F 1/00

(52) U.S. Cl. 430/5

(57) ABSTRACT

A mask for a semiconductor device and a patterning method using the same are disclosed. The mask for a semiconductor device includes a first mask including main patterns constituted by a plurality of split patterns arranged at intervals, and a second mask including first auxiliary patterns disposed corresponding to regions among the plurality of split patterns, and second auxiliary patterns disposed corresponding to edge parts of the plurality of split patterns.

The present application claims priority under 35 U.S.C. 119 to Korean Patent Application No. 10-2007-0084931 (filed on Aug. 23, 2007), which is hereby incorporated by reference in its entirety.

### BACKGROUND

Mask patterning technologies greatly affect the accuracy of a pattern formed on a semiconductor substrate. To enhance the accuracy of the pattern, a mask for a semiconductor device should be precisely designed so that luminosity of light transmitted through the mask can be properly adjusted. To this end, development of a new photosensitizer, a scanner equipped with a high numerical aperture lens, and a modified mask technology have been increasingly needed to overcome technical limitations of optical exposure systems. An optical proximity correction technology has been especially helpful in overcoming the limitations of optical exposure systems.

FIG. 1A shows a mask of a related semiconductor device, and an outline of an image obtained through simulation of the mask. FIG. 1B shows a related mask passed through the optical proximity correction, and an outline of an image obtained through simulation of the mask. A plurality of polygonal cell patterns 1 shown in FIG. 1A are formed on the mask at predetermined intervals. As can be understood from the image outline 2 obtained through simulation of the mask of FIG. 1A, defects are generated on the patterns 1 due to the influence of the optical proximity.

Edge parts 3B of the poly cell patterns 1 are rounded because of diffraction of light. At corner parts 3A of the polygonal cell pattern 1, bridges are generated since the corner parts 3A are not sufficiently exposed. Areas 3C among the polygonal cell patterns 1 are also poorly exposed, thereby causing bridges.

To prevent generation of such defects, patterning may be performed using a mask with an optical proximity correction pattern 10 as shown in FIG. 1B. Referring to FIG. 1B, the defects generated at the edge parts 3B, the corner parts 3A and the areas 3C among the polygonal cell patterns are improved in the image outline 20 obtained through simulation of the mask having the optical proximity correction pattern 10. However, it is difficult to optimize the optical proximity correction pattern 10 for desired sizes when the pattern 10 is under the size of 90 nm due to defects such as pinches and bridges.

### SUMMARY

Embodiments relate to a mask for a semiconductor device and a patterning method using the same, and more particularly, to a mask for a semiconductor device, capable of improving accuracy of line resolution, and a patterning method using the same. Embodiments relate to a mask for a semiconductor device which includes a first mask including main patterns constituted by a plurality of split patterns arranged at intervals, and a second mask including first auxiliary patterns disposed corresponding to regions among the plurality of split patterns, and second auxiliary patterns disposed corresponding to edge parts of the plurality of split patterns.

The plurality of split patterns may be formed as triangles or squares. The plurality of split patterns may be spaced by distances within a range of about 5% to 50% of the resolution limit.

The first auxiliary patterns may be spaced apart from or adjoin the split patterns whereas the second auxiliary patterns are overlapped with the split patterns. The first auxiliary patterns may be spaced from the split patterns whereas the second auxiliary patterns may be separated from or adjoin the split patterns. On the other hand, the first auxiliary patterns may adjoin the split patterns while the second auxiliary patterns may be spaced from the split patterns. When magnification is adjusted, a central coordinate value of at least one of the auxiliary patterns and the split patterns may remain unchanged.

Embodiments relate to a patterning method using the semiconductor device mask which includes preparing a first mask for a semiconductor device including main patterns constituted by a plurality of split patterns arranged at intervals, preparing first auxiliary patterns disposed corresponding to regions among the plurality of split patterns, and second auxiliary patterns disposed corresponding to edge parts of the plurality of split patterns, arranging the first mask and the second mask such that the first auxiliary patterns and the second auxiliary patterns are disposed with regard to the main patterns, and performing a continuous exposure using the first mask and the second mask.

### DRAWINGS

FIG. 1A shows a mask of a related semiconductor device and an outline of an image obtained through simulation of the mask.

FIG. 1B shows a related mask passed through the optical proximity correction, and an outline of an image obtained through simulation of the mask.

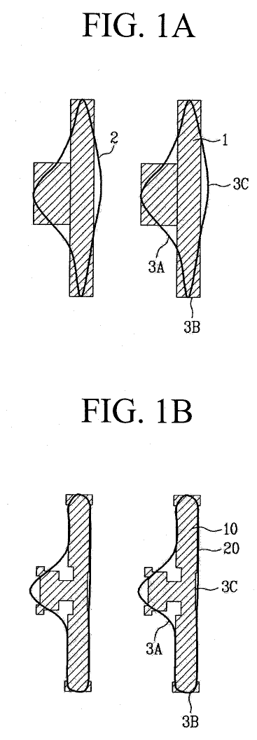

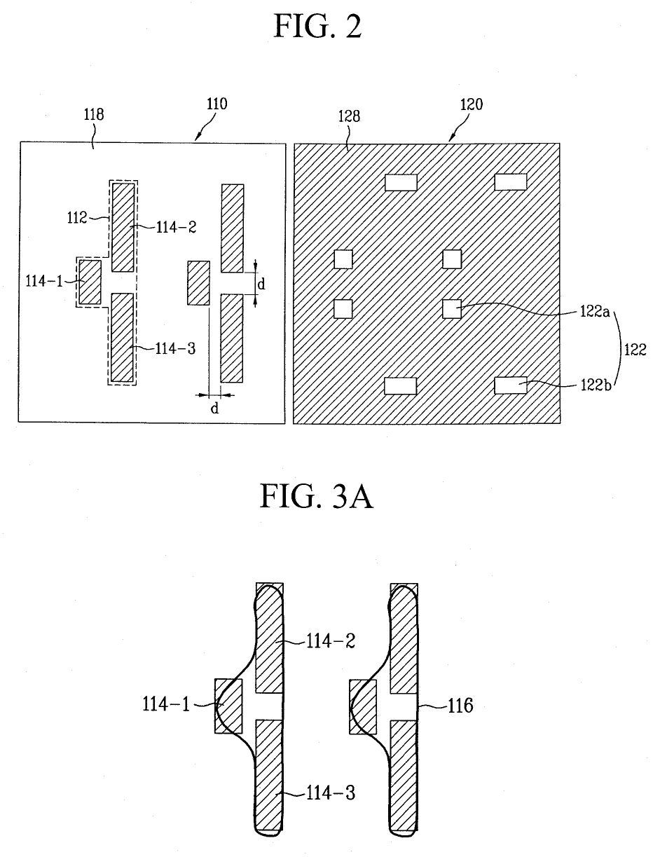

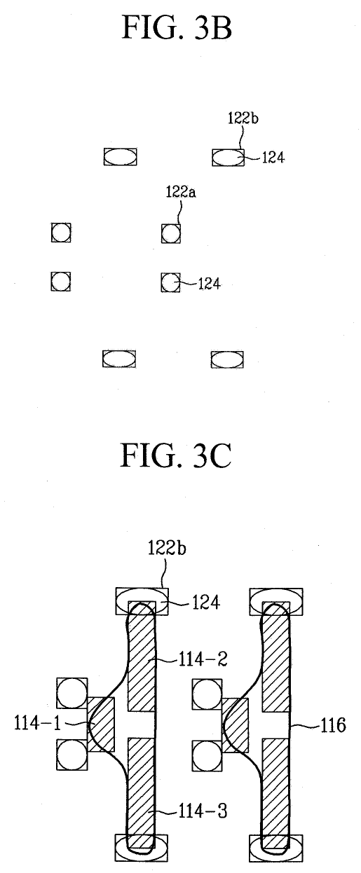

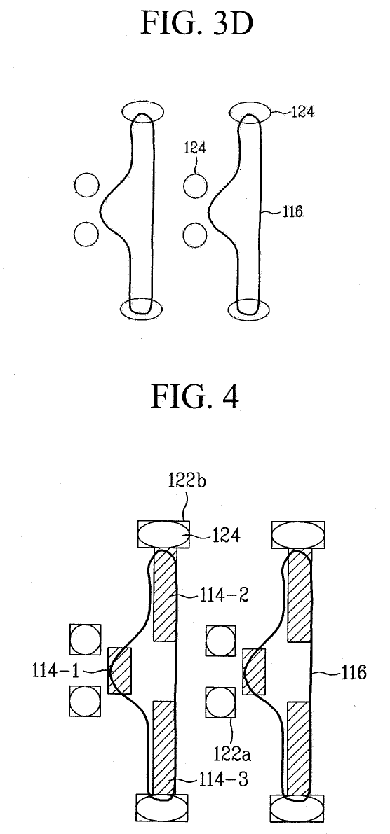

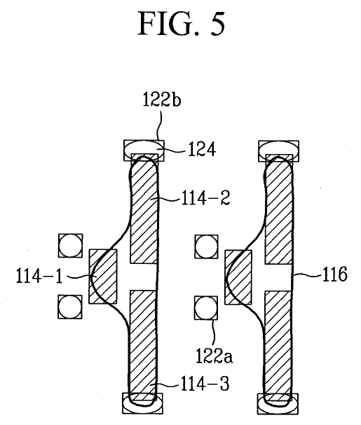

Example FIG. 2 is a plan view of masks of a semiconductor device according to embodiments.

Example FIG. 3A shows an outline of a first image obtained through simulation of the first mask shown in example FIG. 2.

Example FIG. 3B shows an outline of a second image obtained through simulation of a second mask shown in example FIG. 2.

Example FIG. 3C illustrates continuous exposure processes performed with the first and the second masks of example FIG. 2 arranged.

Example FIG. 3D separately shows the first and second image outlines shown in example FIGS. 3A and 3B.

Example FIG. 4 shows a mask of a semiconductor device according to embodiments and an outline of an image obtained through simulation of the mask.

Example FIG. 5 shows a mask of a semiconductor device according to embodiments and an outline of an image obtained through simulation of the mask.

### DESCRIPTION

Example FIG. 2 is a plan view showing a mask for a semiconductor device according to embodiments. Referring to example FIG. 2, the mask includes a first mask 110 including main patterns 112 and a second mask 120 including auxiliary patterns 122. The first mask 110 includes a light shielding region on which a plurality of split patterns 114-1, 114-2 and 114-3 are formed, and a light transmissive region 118 which is the other region excluding the light shielding region. More particularly, the light shielding region includes a light shielding layer formed on a substrate of the mask. The split patterns 114-1, 114-2 and 114-3 prevent transmission of light. The light transmissive region 118 includes the mask substrate which allows transmission of light.

The plurality of split patterns 114-1 to 114-3 together constitute the main patterns 112. The main patterns 112 each have a polygonal shape including plural edges, for example a T-shape, and are arranged at predetermined intervals. The split patterns 114-1 to 114-3, being formed as triangles or squares, are spaced from one another by distances less than a resolution limit. Here, the resolution limit is proportional to an exposure wavelength, and inversely proportional to a numerical aperture of a lens in an optical system, as shown in Expression 1 below:

R=k×(λ/N.A.) Expression 1

In Expression 1, ‘R’ denotes the resolution, ‘k’ denotes a proportional constant, ‘λ’ denotes wavelength of a light source, and ‘N.A.’ denotes the numerical aperture of the lens. That is, the light source wavelength λ and the numerical aperture N.A. determine the resolution R. In lines and spaces less than the resolution R, regular patterns or spaces cannot be made. Only an optical effect is generated. Especially regarding the spaces, the optical effect causes the light shielding patterns to be in effective contact with one another, although allowing transmission of light between the patterns. Accordingly, distances d among the plurality of split patterns 114-1 to 114-3 need to be within a range of 5˜50% of the resolution limit. For instance, if the resolution limit is 90 nm, the plurality of split patterns 114-1 to 114-3 should be separated by 45 nm or less.

The second mask 120 includes a light transmissive region including the auxiliary patterns 122 and a light shielding region 128 which is the other region excluding the light transmissive region. The light shielding area includes a light shielding layer formed on the mask substrate to screen light. The light transmissive region 128 includes the mask substrate which allows transmission of light. The auxiliary patterns 122 include first auxiliary patterns 122a disposed corresponding to regions among the main patterns 112 for the optical proximity correction, and second auxiliary patterns 122b disposed corresponding to edge portions of the main patterns 112.

The first auxiliary patterns 122a adjoins the split pattern 114-1 disposed between the other split patterns 114-2 and 114-3 while the second auxiliary patterns 122b are overlapped with the split patterns 114-2 and 114-3 corresponding to the edge parts of the main patterns 112. The auxiliary patterns 122 prevent generation of the defects at the edge parts of the main patterns 112.

Example FIG. 3A shows a first image outline 116 obtained through simulation of the first mask 110 according to embodiments. Referring to the first image outline 116 of example FIG. 3A, corner parts are larger and better defined than in the related art. Example FIG. 3B shows a second image outline 124 obtained through simulation of the second mask 120. Referring to example FIG. 3B, the second image outline 124 corresponding to the first auxiliary patterns 122a is spaced apart from the first image outline 116. On the other hand, the second image outline 124 corresponding to the second auxiliary patterns 122b is overlapped with the first image outline 116.

By performing continuous optical exposure with the first and the second masks 110 and 120 arranged in the above manner, new optical image outlines can be obtained through composition of the first optical image outline 116 formed by the main patterns 112 and the second optical image outline 124 formed by the auxiliary patterns 122 as shown in example FIG. 3C. The first and the second optical image outlines 116 and 124 before the composition are respectively shown in example FIG. 3D. Referring to example FIG. 3D, the optical images at the corner parts and the edge parts of the main patterns 112 can be made to be more similar to the original shape of the main patterns 112, for example the T-shape, than in the related art.

Example FIG. 4 shows a mask for a semiconductor device according to embodiments, and an image outline obtained through simulation of the mask. The mask for a semiconductor device according to the embodiments as shown in example FIG. 4 is structured in the same manner as the mask according to the first embodiment shown in example FIG. 2, except that the split patterns are smaller than those of the first embodiment. Therefore, detailed description about the aforementioned parts will not be repeated.

The size of split patterns in example FIG. 4 is reduced by about 10% from the split patterns of example FIG. 2. Therefore, the split pattern 114-1 is separated from the first auxiliary patterns 122a while the split patterns 114-2 and 114-3 are adjoining the second auxiliary patterns 122b. Here, the center of the split patterns of example FIG. 4 and the center of the split patterns of example FIG. 2 have the same coordinate value to each other. In other words, when adjustment of the line width of the main patterns 112 is required, magnification of the split patterns is adjusted without causing change of the central coordinate value. The first image outline 116 thus obtained from the reduced split patterns 114-1 to 114-3 is formed at a distance from the second image outline 124 obtained from the auxiliary patterns 122.

Accordingly, a balance of luminosity between the split patterns 114-1 to 114-3 and the auxiliary patterns 122 can be achieved, thereby restraining the optical proximity correction effect as much as possible. Furthermore, since intervals among the 10% reduced split patterns 114-1 to 114-3 are increased compared to in example FIG. 2, the corner parts are larger and more defined as can be appreciated from the first image outline 116. That is, angles of the corner parts can also be adjusted by varying the size of the split patterns 114-1 to 114-3.

Example FIG. 5 shows a mask of a semiconductor device according to embodiments and an outline of an image obtained through simulation of the mask. The mask for a semiconductor device according to embodiments shown in example FIG. 5 is structured in the same manner as the mask according to embodiments shown in example FIG. 2, except that the split patterns are smaller than those of FIG. 2. Therefore, detailed description about the aforementioned parts will not be repeated.

The size of auxiliary patterns 122 in example FIG. 5 is reduced by about 10% from the auxiliary patterns 122 of example FIG. 2. Therefore, the split pattern 114-1 is spaced further from the first auxiliary patterns 122a while the split patterns 114-2 and 114-3 are overlapped with the second auxiliary patterns 122b. Here, the center of the auxiliary patterns 122 of example FIG. 5 and the center of the auxiliary patterns 122 of example FIG. 2 have the same coordinate value. In other words, when adjustment of the line width of the auxiliary patterns 122 is required, the magnification is adjusted without causing a change in the central coordinate value. The second image outline 124 thus obtained from the reduced auxiliary patterns 122 is separated from the first image outline 116 obtained from the split patterns 114-1 at the regions corresponding to first auxiliary patterns 122a while being overlapped with the first outline 116 at the region corresponding to the second auxiliary patterns 122b.

Accordingly, the auxiliary patterns 122 can be defined, decreasing the optical proximity correction effect at the corner parts and the edge parts. As a consequence, excessive compensation of the corner parts and the edge parts can be prevented. As apparent from the above description, a mask for a semiconductor device and a patterning method using the same according to any one of the above-described embodiments has advantages as follows.

First, since main patterns of a first mask are arranged at intervals, the patterning of corner parts can be more precise, thereby achieving patterns more closely matching the original form of the main patterns, as compared to related-art patterns. Second, the optical proximity correction can be optimized by controlling the main patterns and auxiliary patterns independently. Third, use of first and second masks improves optical resolution even in patterns under the size of 90 nm.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a first mask including main patterns constituted by a plurality of split patterns arranged at intervals; and
a second mask including first auxiliary patterns disposed corresponding to regions among the plurality of split patterns, and second auxiliary patterns disposed corresponding to edge parts of the plurality of split patterns.

2. The apparatus of claim 1, wherein the plurality of split patterns are light shielding regions while the other regions of the first mask excluding the light shielding regions are light transmissive regions.

3. The apparatus of claim 1, wherein the first auxiliary patterns and the second auxiliary patterns are light transmissive regions while the other regions of the second mask excluding the light transmissive region are light shielding regions.

4. The apparatus of claim 1, wherein the plurality of split patterns are formed as at least one of triangles and squares.

5. The apparatus of claim 4, wherein the plurality of split patterns are spaced apart from one another by distances less than a resolution limit.

6. The apparatus of claim 5, wherein the plurality of split patterns are spaced by distances within a range of about 5% to 50% of the resolution limit.

7. The apparatus of claim 1, wherein the first auxiliary patterns do not overlap the split patterns whereas the second auxiliary patterns overlap the split patterns.

8. The apparatus of claim 1, wherein the first auxiliary patterns are spaced from the split patterns whereas the second auxiliary patterns adjoin the split patterns.

9. The apparatus of claim 7, wherein, when magnification is adjusted, a central coordinate value of the auxiliary patterns is not changed.

10. The apparatus of claim 7, wherein, when magnification is adjusted, a central coordinate value of the split patterns is not changed.

11. A method comprising:
preparing a first mask for a semiconductor device including main patterns constituted by a plurality of split patterns arranged at intervals;
preparing first auxiliary patterns disposed corresponding to regions among the plurality of split patterns, and second auxiliary patterns disposed corresponding to edge parts of the plurality of split patterns;
arranging the first mask and the second mask such that the first auxiliary patterns and the second auxiliary patterns are disposed with regard to the main patterns; and
performing a continuous exposure using the first mask and the second mask.

12. The method of claim 11, wherein preparing the first mask is performed in such a manner that the plurality of split patterns is a light shielding region while the other region of the first mask excluding the light shielding region is a light transmissive region.

13. The method of claim 11, wherein preparing the second mask is performed in such a manner that the first auxiliary patterns and the second auxiliary patterns form light transmissive regions while the other remaining region of the second mask excluding the light transmissive regions form a light shielding region.

14. The method of claim 11, wherein preparing the second mask includes forming the plurality of split patterns as at least one of triangles and squares.

15. The method of claim 11, wherein preparing the second mask is performed in such a manner that the plurality of split patterns are spaced apart from one another by distances less than a resolution limit.

16. The method of claim 15, wherein preparing the second mask is performed in such a manner that the plurality of split patterns are spaced by distances within a range of about 5% to 50% of the resolution limit.

17. The method of claim 11, wherein preparing the second mask is performed in such a manner that the first auxiliary patterns are separated from the split patterns, and the second auxiliary patterns overlap the split patterns.

18. The method of claim 11, wherein preparing the second mask is performed in such a manner that the first auxiliary patterns are spaced from the split patterns and the second auxiliary patterns adjoin the split patterns.

19. The method of claim 11, wherein when magnification is adjusted, a central coordinate value of the auxiliary patterns is not changed.

20. The method of claim 11, wherein when magnification is adjusted, a central coordinate value of the split patterns is not changed.
